(19) United States
(12) Patent Application Publication
(10) Pub. No.: US 2021/0104658 A1
(43) Pub. Date: Apr. 8, 2021

(54) MULTILAYER PIEZOELECTRIC DEVICE

(71) Applicant: TDK CORPORATION, Tokyo (JP)

(72) Inventors: Makoto ISHIZAKI, Tokyo (JP); Masaharu HIRAKAWA, Tokyo (JP)

(73) Assignee: TDK CORPORATION, Tokyo (JP)

(21) Appl. No.: 17/064,951

(22) Filed: Oct. 7, 2020

(30) Foreign Application Priority Data
Oct. 8, 2019 (JP) 2019-185070

(51) Int. Cl. H01L 41/312; H01L 41/083; H01L 41/047

(52) U.S. Cl. CPC H01L 41/312; H01L 41/0471; H01L 41/0472; H01L 41/083

(57) ABSTRACT

A multilayer piezoelectric device includes a laminated body and an external electrode. The laminated body includes a piezoelectric layer formed along a plane including a first axis and a second axis intersecting each other and an internal electrode layer laminated on the piezoelectric layer. The external electrode is electrically connected to the internal electrode layer. The internal electrode layer includes a first slit parallel to the first axis and a second slit parallel to the second axis.

### BACKGROUND OF THE INVENTION

The present invention relates to a multilayer piezoelectric device.

A multilayer piezoelectric device has a structure in which internal electrodes and piezoelectric layers are laminated and can have a larger displacement amount and a larger driving force per unit volume compared to those of a non-multilayer piezoelectric device. In the multilayer structure, there is a difference in thermal shrinkage behavior between the internal electrodes and the piezoelectric layers, and a laminated body is thereby easy to have an abnormal deformation of warp, swell, etc. Moreover, the shrinkage disturbance of the piezoelectric layers by the internal electrodes may generate cracks or so inside the laminated body.

In particular, the multilayer piezoelectric device for haptics, speakers, etc. is lately required to have a thinner and wider element body. In such a case, the above-mentioned abnormal deformation of the laminated body is easy to occur, and it becomes more difficult to restrain cracks.

In Patent Document 1, holes where no conductor exists are formed in internal electrodes to prevent them from disturbing the motion of piezoelectric layers. However, the technique of forming the holes disclosed in Patent Document 1 cannot sufficiently restrain an abnormal deformation or cracking of a laminated body and cannot sufficiently deal with the thinning and widening of an element body.

Patent Document 1: JP2006287480 (A)

### BRIEF SUMMARY OF INVENTION

The present invention has been achieved under such circumstances. It is an object of the invention to provide a multilayer piezoelectric device having a restrained abnormal deformation of a laminated body and fewer cracks generated in the laminated body.

To achieve the above object, a multilayer piezoelectric device according to the present invention includes:

a laminated body including:
a piezoelectric layer formed along a plane including a first axis and a second axis intersecting each other; and
an internal electrode layer laminated on the piezoelectric layer; and

an external electrode electrically connected to the internal electrode layer,

wherein the internal electrode layer includes a first slit parallel to the first axis and a second slit parallel to the second axis.

The present inventors have earnestly studied and consequently found that a shrinkage stress generated in the internal electrode layer can be reduced more effectively than before by forming both the first slit parallel to the first axis (X-axis±45 degrees or less) and the second slit parallel to the second axis (Y-axis±45 degrees or less) in the internal electrode layer. As a result, the multilayer piezoelectric device according to the present invention can restrain an abnormal deformation (warp, swell, etc.) of the laminated body in a firing step and has an improved flatness. In addition, the multilayer piezoelectric device according to the present invention can further reduce cracks generated in the laminated body than before.

In particular, the first slit and the second slit includes an outer circumferential first slit and an outer circumferential second slit, and these slits are formed on an outer circumference of the internal electrode layer. Here, the outer circumference of the internal electrode layer is a portion contacted with an outer circumferential edge of an internal electrode pattern. The outer circumferential first slit and the outer circumferential second slit are open outward at the outer circumferential edge of the internal electrode pattern.

In the internal electrode layer of the multilayer piezoelectric device, if heat is added by binder removal treatment, firing treatment, or the like, a shrinkage stress is generated from the outer circumferential edge of the internal electrode layer, where heat is easy to add, toward the inner side, where heat is hard to add. In the multilayer piezoelectric device according to the present invention, as mentioned above, since the outer circumferential first slit and the outer circumferential second slit are formed on the outer circumference of the internal electrode layer, the stress by thermal shrinkage is more easily reduced. As a result, it is possible to more effectively restrain the abnormal deformation and the generation of cracks in the laminated body.

Preferably, both a width in a short direction of the outer circumferential first slit and a width in a short direction of the outer circumferential second slit are 0.03 mm or more and 0.6 mm or less. In the multilayer piezoelectric device according to the present invention, when the widths of the outer circumferential slits are controlled to the above-mentioned range, it is possible to appropriately restrain an abnormal deformation of the laminated body while piezoelectric characteristics are maintained.

Preferably, the outer circumferential first slit and the outer circumferential second slit have a total number of at least four slits. In the multilayer piezoelectric device according to the present invention, when the outer circumferential first slit and the outer circumferential second slit include a plurality of slits, the flatness of the laminated body tends to further improve.

In particular, the internal electrode layer can have a substantially quadrangular shape from plan view on the plane, and the outer circumferential first slit and the outer circumferential second slit are preferably formed near a corner of the internal electrode layer.

When a lamination surface (flat surface) is substantially quadrangular, the shrinkage stress generated in the internal electrode layer particularly affects the corner of the internal electrode layer. In the prior arts, the corner of the laminated body is thereby particularly warped. Unlike the prior arts, the multilayer piezoelectric device according to the present invention can have a further improved flatness of the laminated body by forming the outer circumferential first slit and the outer circumferential second slit in the surroundings of the corner.

Preferably, a corner of the internal electrode layer and corners of the outer circumferential first slit and the outer circumferential second slit are rounded with a radius of curvature of 0.1 mm or more.

When a DC electric field is applied in polarization, the electric field tends to concentrate on the surroundings of the corner of the internal electrode layer. In particular, when the piezoelectric layer is made of a lead-free material, a rated voltage for polarization is high, and a short circuit is thereby easily generated at the corner of the internal electrode layer in polarization. In the multilayer piezoelectric device according to the present invention, an electric field can be prevented from concentrating on the corner by rounding the corner of the internal electrode layer and the corner of the outer circumferential slit constituting a part of the outer circumferential edge of the internal electrode layer. As a result, the multilayer piezoelectric device according to the present invention can have a large polarization rate and a further improved displacement amount.

The first slit and the second slit can include at least one of inner first slits and at least one of inner second slits. Preferably, an inner slit pattern is formed on an inner side of the internal electrode layer, and the inner slit pattern has a combined pattern of at least two of the inner first slits or at least two of the inner second slits. Here, the inner side of the internal electrode layer means an inner side of the outer circumferential edge of the inner electrode pattern, and the inner slit pattern includes a slit that is not open at the outer circumferential edge of the internal electrode layer.

The piezoelectric layer generates a mechanical displacement by application of electric voltage via the internal electrode layer, but at this time, the internal electrode layer itself does not generate a mechanical displacement. Thus, the internal electrode layer may disturb a mechanical displacement of the piezoelectric layer. In the multilayer piezoelectric device according to the present invention, the displacement disturbance by the internal electrode layer can be reduced by forming the above-mentioned inner slit pattern along with the outer circumferential slit on the internal electrode layer. As a result, cracks generated in the laminated body can be reduced more effectively, and the displacement amount of the multilayer piezoelectric device is further improved.

In particular, preferably, the inner slit pattern has a pattern in which a plurality of inner first slits and a plurality of inner second slits are combined in a dashed grid manner. When the inner slit pattern is formed in a dashed grid manner, the displacement amount of the multilayer piezoelectric device is further improved.

Incidentally, preferably, both a width in a short direction of the inner first slit and a width in a short direction of the inner second slit are also 0.03-0.6 mm in the inner slit pattern. In the multilayer piezoelectric device according to the present invention, when the widths of the inner slit are controlled to the above-mentioned range, it is possible to appropriately restrain generation of cracks while piezoelectric characteristics are maintained.

In the present invention, a plurality of piezoelectric layers and a plurality of internal electrode layers can alternately be laminated in the laminated body. In this case, preferably, the inner slit patterns of two internal electrode layers next to each other via the piezoelectric layer are locationally shifted without overlapping with each other in a lamination direction on an optional cross section of the laminated body perpendicular to the first axis or the second axis. In the above-mentioned lamination structure, the multilayer piezoelectric device according to the present invention has a further improved flatness of the laminated body.

Moreover, when the laminated body includes a plurality of piezoelectric layers and a plurality of internal electrode layers, it is preferable to employ a multilayer structure in which coverage rates of the internal electrode layers per one layer gradually increase or decrease from a lowermost layer to an uppermost layer in a lamination direction on an optional cross section of the laminated body perpendicular to the first axis or the second axis. In this multilayer structure, the multilayer piezoelectric device according to the present invention can control piezoelectric characteristics to desired values.

In the above-mentioned case, preferably, a difference of the coverage rates between the internal electrode layer having a maximum coverage rate and the internal electrode layer having a minimum coverage rate is 3.0% or more and 15% or less.

The multilayer piezoelectric device according to the present invention can be utilized as a conversion element for electrical energy and mechanical energy. For example, the multilayer piezoelectric device according to the present invention is applicable to drive actuators, haptics devices, piezoelectric buzzers, piezoelectric sounders, ultrasonic motors, speakers, etc. and is particularly advantageously utilized for haptics and piezoelectric speakers.

### BRIEF DESCRIPTION OF DRAWINGS

FIG. 1 is a schematic perspective view illustrating a multilayer piezoelectric device according to First Embodiment of the present invention;

FIG. 2 is a cross-sectional view of a main part cut along the II-II line shown in FIG. 1;

FIG. 3A is a plane view illustrating an internal electrode pattern included in the multilayer piezoelectric device of FIG. 1;

FIG. 3B is an enlarged plane view of a main part illustrating an internal electrode pattern according to Second Embodiment of the present invention;

FIG. 4 is an exploded perspective view of the laminated body shown in FIG. 1;

FIG. 5A is a plane view illustrating an internal electrode pattern according to Third Embodiment of the present invention;

FIG. 5B is a plane view illustrating an internal electrode pattern according to Third Embodiment of the present invention;

FIG. 6 is a cross-sectional view of a main part of a multilayer piezoelectric device according to Third Embodiment of the present invention;

FIG. 7 is a cross-sectional view of a main part of a multilayer piezoelectric device according to Fourth Embodiment of the present invention;

FIG. 8A is a plane view illustrating an internal electrode pattern according to Example 1;

FIG. 8B is a plane view illustrating an internal electrode pattern according to Example 2;

FIG. 8C is a plane view illustrating an internal electrode pattern according to Example 4;

FIG. 9A is a plane view illustrating an internal electrode pattern according to Comparative Example 1; and

FIG. 9B is a plane view illustrating an internal electrode pattern according to Comparative Example 2.

### DETAILED DESCRIPTION OF INVENTION

Hereinafter, the present invention is explained based on the embodiments shown in the figures.

### First Embodiment

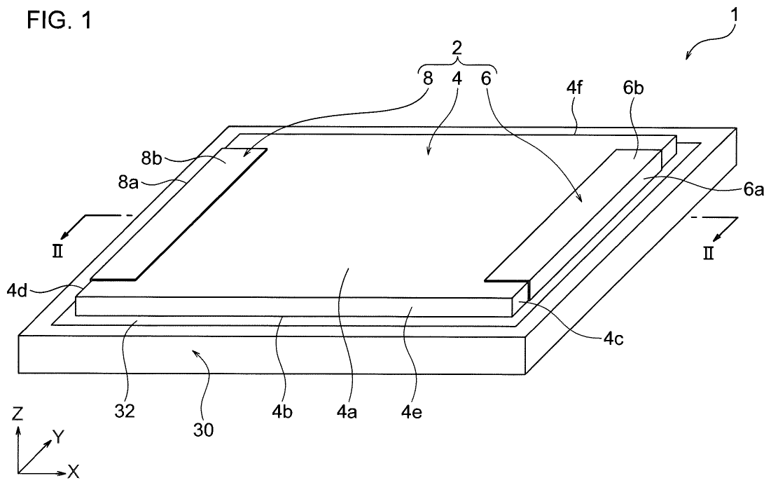

As shown in FIG. 1, a piezoelectric device 1 according to the present embodiment includes a multilayer piezoelectric device 2 and a vibration plate 30. The multilayer piezoelectric device 2 is attached on the vibration plate 30 via an adhesive layer 32.

In the piezoelectric device 1, the vibration plate 30 is used for amplifying the displacement of the multilayer piezoelectric device 2. For example, when the piezoelectric device 1 is used for haptics, a tactile feedback is obtained by the vibration of the vibration plate 30. When the piezoelectric device 1 is used for acoustic applications, such as piezoelectric buzzers and piezoelectric speakers, a sound is generated by the vibration of the vibration plate 30.

The vibration plate 30 is made of any elastic material, such as metal material of Ni, Ni—Fe alloy, brass, stainless steel, etc. The thickness and size of the vibration plate 30 are appropriately determined based on usage of the piezoelectric device 1 and are not limited. For example, the thickness of the vibration plate 30 can be 0.1 mm to 0.5 mm, and the size of the vibration plate 30 can be about 1-3 times as large as the multilayer piezoelectric device 2 from plan view.

As mentioned above, the multilayer piezoelectric device 2 is attached on the vibration plate 30 via an adhesive layer 32. The adhesive layer 32 is made of a connection material, such as epoxy resin, acrylic resin, silicone resin, and butyral resin.

Preferably, however, the adhesive layer 32 has an electrical insulation without containing a conductive filler. When the adhesive layer 32 has an electrical insulation, there is no short circuit between a first external electrode 6 and a second external electrode 8 mentioned below even if the vibration plate 30 is made of metal.

Preferably, the thickness of the adhesive layer 32 is 10 μm to 1000 μm. When the thickness of the adhesive layer 32 is in the above-mentioned range, a displacement generated from the multilayer piezoelectric device 2 can effectively be transmitted to the vibration plate 30 while maintaining an adhesion between the multilayer piezoelectric device 2 and the vibration plate 30.

In the present embodiment, as shown in FIG. 1, the multilayer piezoelectric device 2 is structured by a laminated body 4, a first external electrode 6, and a second external electrode 8.

The laminated body 4 has a substantially rectangular parallelepiped shape and has a front surface 4a and a back surface 4b substantially perpendicular to the Z-axis direction, side surfaces 4c and 4d substantially perpendicular to the X-axis direction, and side surfaces 4e and 4f substantially perpendicular to the Y-axis direction. Incidentally, an insulating protective layer (not illustrated) may be formed on the side surfaces 4c-4f of the laminated body 4 except for areas where the external electrodes 6 and 8 are formed. In the figures, the X-axis, the Y-axis, and the Z-axis are substantially perpendicular to each other.

For example, the laminated body 4 can have a width in the X-axis direction of 3 mm to 1000 mm, a width in the Y-axis direction of 3 mm to 1000 mm, and a height in the Z-axis direction of 0.03 mm to 800 mm. In the present embodiment, the width in the X-axis direction and the width in the Y-axis direction are preferably 250 mm or more, and the height is preferably 300 μm or less.

The first external electrode 6 has a first side-surface section 6a formed along the side surface 4c of the laminated body 4 and a first front-surface section 6b formed along the front surface 4a of the laminated body 4. The first side-surface section 6a and the first front-surface section 6b have a substantially rectangular shape and are connected to each other at their intersection. Incidentally, the first side-surface section 6a and the first front-surface section 6b are illustrated separately in the figures, but are actually formed integrally.

The second external electrode 8 is formed similarly to the first external electrode 6. That is, the second external electrode 8 has a second side-surface section 8a formed along the side surface 4d of the laminated body 4 and a second front-surface section 8b formed along the front surface 4a of the laminated body 4, and the second side-surface section 8a and the second front-surface section 8b are connected to each other at their intersection. Incidentally, the first front-surface section 6b and the second front-surface section 8b are formed away from each other and electrically insulated on the front surface 4a of the laminated body 4. The first side-surface section 6a and the second side-surface section 8a are electrically insulated via the adhesive layer 32 on the back surface 4b of the laminated body 4.

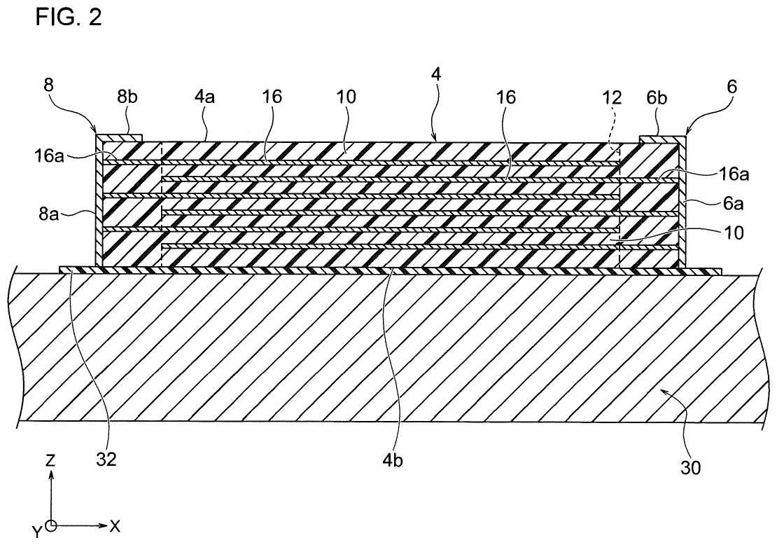

As shown in FIG. 2, the laminated body 4 has an internal structure where piezoelectric layers 10 and internal electrode layers 16 are alternately laminated along the lamination direction (Z-axis direction). The internal electrode layers 16 are laminated so that leading portions 16a are alternately exposed to the side surface 4c or 4d of the laminated body 4 and are electrically connected to the first external electrode 6 or the second external electrode 8 via the exposed leading portions 16a.

In the present embodiment, the piezoelectric layers 10 at a core part of the laminated body 4 has a piezoelectric active section 12 sandwiched by the internal electrode layers 16. That is, the piezoelectric active section 12 means a region surrounded by the dotted line shown in FIG. 2 and has a mechanical displacement generated by voltage application via the first external electrode 6 and the second external electrode 8 having mutually different polarities.

The piezoelectric layers 10 are made of any material exhibiting piezoelectric effect or inverse piezoelectric effect, such as PbZrₓTi₁₋ₓO₃ (PZT), BaTiO₃ (BT), BiNaTiO₃ (BNT), BiFeO₃ (BFO), (Bi₂O₂)²⁺(Aₘ₋₁BₘO₃ₘ₊₁)²⁻ (BLSF), and (K, Na)NbO₃ (KNN). In particular, a lead-free material is preferably used. The piezoelectric layers 10 may contain a sub component for characteristic improvement or so. The amount of the sub component is appropriately determined based on desired characteristics.

Incidentally, each of the piezoelectric layers 10 has any thickness, but preferably has a thickness of about 0.5-100 μm in the present embodiment. The lamination number of piezoelectric layers 10 is two or more and has no upper limit, but is preferably about 3-20. The lamination number of piezoelectric layers 10 is appropriately determined based on usage of the multilayer piezoelectric device 2.

The internal electrode layers 16 are made of any conductive material, such as noble metal of Ag, Pd, Au, Pt, etc., their alloy (Ag—Pd or so), base metal of Cu, Ni, etc., and their alloy. Each of the internal electrode layers 16 also has any thickness, but preferably has a thickness of about 0.5-2.0 μm. The lamination number of internal electrode layers 16 is determined based on the lamination number of piezoelectric layers 10.

The first external electrode 6 and the second external electrode 8 are also made of a conductive material and can be made of a similar material to the conductive material constituting the internal electrodes. The first external electrode 6 and the second external electrode 8 may be formed by mixing a conductive metal powder of Ag, Cu, etc. with a glass powder of SiO₂ etc. and firing the mixture. Incidentally, a plating layer, a sputtered layer, or the like containing the above-mentioned various metals may further be formed outside the first external electrode 6 and the second external electrode 8.

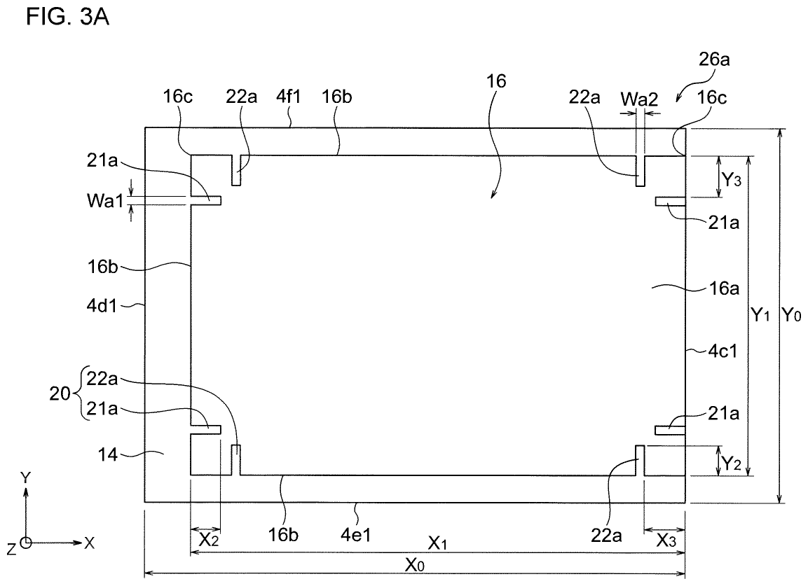

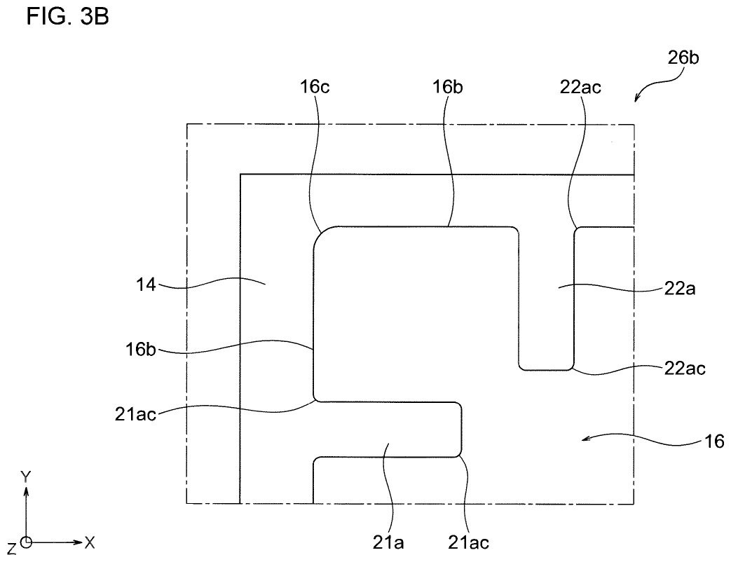

FIG. 3A is a schematic plane view illustrating an internal electrode pattern 26a included in the laminated body 4. In the lower part of the Z-axis in FIG. 3A, the piezoelectric layer 10 exists along the plane including the X-axis and the Y-axis and have sides 4c1-4f1 corresponding to the side surfaces 4c-4f of the laminated body 4 (see FIG. 1). Thus, the internal electrode pattern 26a is laminated on the surface of each of the piezoelectric layers 10 and has a substantially rectangular plane view shape.

In the internal electrode pattern 26a shown in FIG. 3A, the leading portions 16a of the internal electrode layers 16 are exposed to the side 4c1. On the other hand, outer circumferential edges 16b of the internal electrode layers 16 are not exposed to any of the sides 4d1-4f1 at locations excluding the leading portions 16a. That is, in the plane view shown in FIG. 3A, an area of the internal electrode layers 16 (X1×Y1) is smaller than that of the piezoelectric layers 10 (X0×Y0), and a non-cover part 14, which is not covered with the internal electrode layers 16, exists on the surface of the piezoelectric layers 10.

Specifically, a width X1 of the internal electrode layers 16 in the X-axis direction can be about 0.95-0.999 times as large as a width X0 of the piezoelectric layers 10 in the X-axis direction, and a width Y1 of the internal electrode layers 16 in the Y-axis direction can be about 0.95-0.999 times as large as a width Y0 of the piezoelectric layers 10 in the Y-axis direction. When the area of the internal electrode layers 16 is controlled in the above-mentioned range, it is possible to prevent the short circuit of the internal electrode layers 16 next to each other in the lamination direction while sufficiently securing the region of the piezoelectric active section 12.

In the present embodiment, a first slit 21 substantially parallel to the X-axis and a second slit 22 substantially parallel to the Y-axis are formed on the internal electrode layers 16. Here, the slits mean a location where a conductor constituting the internal electrode layers 16 does not exist on the internal electrode pattern 26a. That is, the piezoelectric layers 10 exist in the first slit 21 and the second slit 22 in the lamination state.

As for each of the first slit 21 and the second slit 22, it is necessary to form at least one or more slits. The details are mentioned below, but when both of the first slit 21 and the second slit 22 are formed, the flatness of the laminated body 4 improves, and cracks generated in the laminated body 4 can be restrained. These effects can further be enhanced by devising the formation location or number of each of the slits 21 and 22. In First Embodiment, the details are explained in case of forming an outer circumferential slit pattern 20 by combining the first slit 21 and the second slit 22.

In the internal electrode pattern 26a according to First Embodiment, as shown in FIG. 3A, an outer circumferential slit pattern 20 is formed on an outer circumference of the internal electrode layers 16. The outer circumferential slit pattern 20 includes an outer circumferential first slit 21a substantially parallel to the X-axis and an outer circumferential second slit 22a substantially parallel to the Y-axis. Here, the outer circumference of the internal electrode layers 16 is a portion contacted with the outer circumferential edges 16b of the internal electrode layers 16, and the outer circumferential first slit 21a and the outer circumferential second slit 22a are open outward at the outer circumferential edges 16b of the internal electrode layers 16.

In particular, the total number of slits included in the outer circumferential slit pattern 20 is eight in FIG. 3A. When categorized, four outer circumferential first slits 21a are formed, and four outer circumferential second slits 22a are formed.

As shown in FIG. 3A, both of the outer circumferential first slits 21a and the outer circumferential second slits 22a are formed near corners 16c of the internal electrode layers 16. Specifically, “near corners 16c” means an area indicated by the references X3 and Y3 in FIG. 3A. The reference Y3 represents a distance from the corner 16c to the outer circumferential first slit 21a and means a formation location of the outer circumferential first slit 21a in the Y-axis direction. On the other hand, the reference X3 represents a distance from the corner 16c to the outer circumferential second slit 22a and means a formation location of the outer circumferential second slit 22a in the X-axis direction.

In the present embodiment, Y3 is preferably about 1/7-½ (more preferably, about 1/7) of the width Y1 of the internal electrode layers 16 in the Y-axis direction. Meanwhile, X3 is also preferably about 1/7-½ (more preferably, about 1/7) of the width X1 of the internal electrode layers 16 in the X-axis direction. In the present embodiment, the outer circumferential first slits 21a and the outer circumferential second slits 22a are preferably formed in areas where X3 and Y3 fall in the above-mentioned ranges (i.e., near the corners 16c).

The width Wa1 of the outer circumferential first slits 21a in the short direction (Y-axis direction) can be 0.01 mm to 0.8 mm and is preferably 0.03 mm to 0.6 mm. The length X2 of the outer circumferential first slits 21a in the longitudinal direction (X-axis direction) can be about 1/10- 1/7 (preferably, ⅛ or less) of the width X1 of the internal electrode layers 16 in the X-axis direction (X2/X1).

The outer circumferential second slits 22a have a similar size to the outer circumferential first slits 21a. That is, the width Wa2 of the outer circumferential second slits 22a in the short direction (X-axis direction) can be 0.01 mm to 0.8 mm and is preferably 0.03 mm to 0.6 mm. The length Y2 of the outer circumferential second slits 22a in the longitudinal direction (Y-axis direction) can be about 1/10- 1/7 (preferably, ⅛ or less) of the width Y1 of the internal electrode layers 16 in the Y-axis direction (Y2/Y1).

In the design of each slit (21a, 22a), the outer circumferential first slits 21a and the outer circumferential second slits 22a are preferably formed to be separate without connecting with each other in the surroundings of the corner 16c. That is, preferably, the internal electrode layer 16 is not separated by the outer circumferential first slits 21a or the outer circumferential second slits 22a, but is formed integrally as a single electrode on a single internal electrode pattern 26a. When the internal electrode layer 16 is formed integrally and continuously, it is possible to increase an effective electrode area for appearance of piezoelectric effect, and piezoelectric characteristics (particularly, displacement) of the multilayer piezoelectric device 2 become favorable.

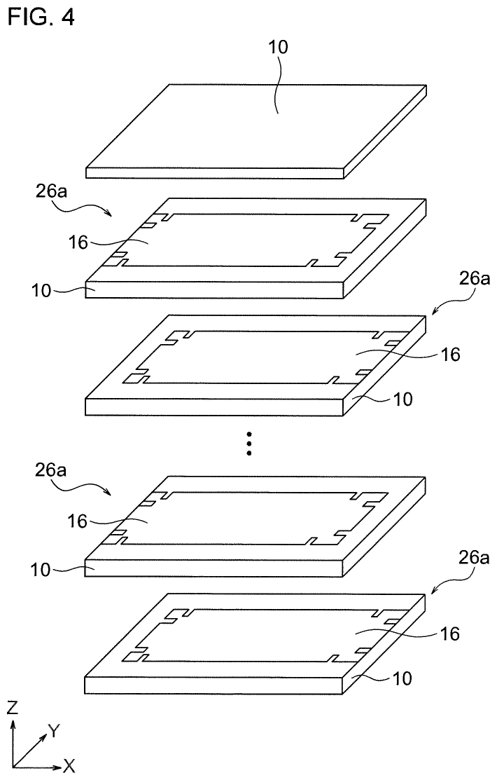

FIG. 4 is an exploded perspective view of the laminated body 4. When three or more piezoelectric layers 10 are laminated as shown in FIG. 4, multiple internal electrode patterns 26a are laminated alternately via the piezoelectric layers 10.

In FIG. 4, the internal electrode pattern 26a at the second layer has a form where the internal electrode pattern 26a at the first layer is rotated by 180 degrees around the Z-axis. That is, the leading portion 16a of the internal electrode layer 16 is exposed to the side 4d1 on the internal electrode pattern 26a at the second layer. When a plurality of piezoelectric layers 10 and internal electrode patterns 26a is laminated as shown in FIG. 4, it is possible to increase a displacement amount and a driving force compared to a non-multilayer piezoelectric device.

In the two internal electrode patterns 26a next to each other via the piezoelectric layer 10 (e.g., at the first layer and the second layer), the outer circumferential slit patterns 20 included in the patterns 26a may overlap with each other in the lamination direction or may be locationally shifted without overlapping with each other in the lamination direction.

To confirm a form of the outer circumferential slit pattern 20 of each of the internal electrode layers 16 under a state of the piezoelectric device 1 (finished product), cross sections of the laminated body 4 are observed by scanning electron microscope (SEM) or so. Specifically, the formation location and size of the outer circumferential first slit 21a can be determined by a SEM observation of Y-Z cross sections of the laminated body 4 along the X-axis at predetermined intervals. Likewise, the formation location and size of the outer circumferential second slit 22a can be determined by a SEM observation of X-Z cross sections of the laminated body 4 as shown in FIG. 2 along the Y-axis at predetermined intervals.

However, the outer circumferential slit pattern 20 of the finished product can be determined by any other method excluding the above-mentioned method and may be, for example, determined by cutting only the surroundings of the corners of the multilayer piezoelectric device 2 and observing X-Y cross sections of cut samples by SEM.

Next, a method of manufacturing the piezoelectric device 1 according to the present embodiment is explained. The piezoelectric device 1 according to the present embodiment is manufactured by any method and can be, for example, manufactured by the following method.

A step of manufacturing the laminated body 4 constituting the multilayer piezoelectric device 2 is initially explained. In the step of manufacturing the laminated body 4, prepared are ceramic green sheets to be the piezoelectric layers 10 after firing and a conductive paste to be the internal electrode layers 16 after firing.

For example, the ceramic green sheets are manufactured in the following manner. First, a raw material of the piezoelectric layers 10 is uniformly mixed by wet mixing or so, dried, and calcined with appropriately determined firing conditions, and the calcined powder is pulverized in wet manner. Then, the pulverized calcined powder is added with a binder to be turned into a slurry. The slurry is turned into sheets by doctor blade method, screen printing method, or the like and dried to obtain ceramic green sheets. Incidentally, the raw material of the piezoelectric layers 10 may contain unavoidable impurities.

Next, an electrode paste containing a conductive material is applied onto the ceramic green sheets by printing method or so. At this time, the electrode paste is applied to form the internal electrode pattern 26a shown in FIG. 3A. The patterning is carried out by any known method. Green sheets where an internal electrode paste film is formed with a predetermined pattern are thereby obtained.

Next, the prepared green sheets are laminated in a predetermined order. That is, as shown in FIG. 4, the prepared green sheets are laminated so that the internal electrode patterns 26a alternately face opposite direction. Only the ceramic green sheet is laminated on the uppermost layer in the Z-axis constituting the front surface 4a of the laminated body 4 after firing.

After the green sheets are laminated, they are bonded with pressure, subjected to necessary steps (e.g., drying step, binder removal step), and fired to obtain the laminated body 4. When the internal electrode layers are made of a noble metal (e.g., Ag—Pd alloy), the firing is preferably carried out at a furnace temperature of 800-1200° C. with atmospheric pressure conditions. When the internal electrode layers are made of a base metal (e.g., Cu, Ni), the firing is preferably carried out at an oxygen partial pressure of 1×10⁻⁷ to 1×10⁻⁹ MPa and a furnace temperature of 800-1200° C.

The first external electrode 6 and the second external electrode 8 are formed on the laminated body 4 subjected to a sintering step by sputtering, evaporation, plating, dip coating, or the like. The first external electrode 6 is formed on from the front surface 4a to the side surface 4c of the laminated body 4, and the second external electrode 8 is formed on from the front surface 4a to the side surface 4d of the laminated body 4. To form an insulating layer, an insulating resin may be applied on the side surfaces 4d-4f of the laminated body 4 on which the external electrodes 6 and 8 are not formed. The multilayer piezoelectric device 2 including the laminated body 4, the first external electrode 6, and the second external electrode 8 is thereby obtained.

Next, the obtained multilayer piezoelectric device 2 is attached on the vibration plate 30. In this step, an adhesive material constituting the adhesive layer 32 is initially applied and thinly spread on the surface of the vibration plate 30. After that, the multilayer piezoelectric device 2 is adhered on the vibration plate by pressing or so. At this time, the pressing force against the element body is preferably applied to a central part of the laminated body 4.

Before or after the vibration plate is bonded, a polarization treatment is carried out so that the piezoelectric layers 10 have piezoelectric activity. The polarization is carried out by applying a DC electric field of 1-10 kV/mm to the first external electrode 6 and the second external electrode 8 in an insulating oil of about 80-120 degrees. Incidentally, the DC electric field to be applied depends upon the material constituting the piezoelectric layers 10. The piezoelectric device 1 shown in FIG. 1 is obtained through the steps.

Incidentally, a process of obtaining a single multilayer piezoelectric device 2 is illustrated in the above, but a green sheet on which multiple internal electrode patterns 26a are formed in a single sheet may be used. An aggregate laminated body formed with such a sheet is appropriately cut before or after firing, and a plurality of elements having the shape as shown in FIG. 1 is finally obtained.

In the present embodiment, both of the first slits 21 parallel to the X-axis and the second slits 22 parallel to the Y-axis are formed on the internal electrode layers 16. In particular, in First Embodiment, the outer circumferential slit pattern 20 including the outer circumferential first slits 21a (corresponding to the first slits 21) and the outer circumferential second slits 22a (corresponding to the second slits 22) is formed on the outer circumference of the internal electrode layers 16.

Due to the above-mentioned structure, the multilayer piezoelectric device 2 according to the present embodiment can prevent the laminated body 4 from being deformed abnormally (warp, swell, etc.) in the firing step and has an improved flatness. In addition, the multilayer piezoelectric device 2 according to the present embodiment can have fewer cracks generated in the laminated body 4 more than before. The reason why such effects on less deformation and fewer cracks appear is conceivable, for example, as below.

In the laminated body 4 of the multilayer piezoelectric device 2, the piezoelectric layers 10 and the internal electrode layers 16 shrink in volume in the above-mentioned firing step. At this time, the behaviors in thermal shrink are different from each other between the piezoelectric layers 10 and the internal electrode layers 16. Since the shrinkage factor of the internal electrode layers 16 is normally larger than that of the piezoelectric layers 10, a shrinkage stress is generated in the internal electrode layers 16, and a tensile stress is generated in the piezoelectric layers 10. It is conceivable that the stresses generated inside the laminated body 4 cause an abnormal deformation (warp, swell, etc.) or cracks in the laminated body 4. If the laminated body 4 has an abnormal deformation or cracks, the displacement of the multilayer piezoelectric device 2 is disturbed, and sufficient piezoelectric characteristics cannot be obtained.

In particular, it is conceivable that the stress generated in the internal electrode layers 16 is generated from the outer circumference of the internal electrode layers 16, where heat is easy to add, toward the inner side, where heat is hard to add. In the present embodiment, the slits are formed along both of the X-axis direction and the Y-axis direction corresponding to the directivity of this stress. In the present embodiment, it is thereby conceivable that it is effectively reduce the stress generated by the difference in shrinkage between the internal electrode layers 16 and the piezoelectric layers 10.

In the present embodiment, since the outer circumferential slit pattern 20 is formed on the outer circumference of the internal electrode layers 16, which is particularly easily affected by the stresses, the stresses are more easily reduced. In the present embodiment, it is thereby possible to more effectively restrain the generation of an abnormal deformation and cracks of the laminated body. In addition, the multilayer piezoelectric device 2 according to the present embodiment can have the laminated body 4 with a favorable flatness and sufficiently restrain cracks generated in the laminated body 4 even if the laminated body 4 is thinned to have a height of 300 μm or less or widened to have a width of 250 mm or more.

In the present embodiment, as shown in FIG. 3A, the total number of outer circumferential first slits 21a and outer circumferential second slits 22a is preferably at least four or more. When a plurality of outer circumferential first slits 21a and outer circumferential second slits 22a is formed in this manner, it is possible to further improve the flatness of the laminated body 4.

In the present embodiment, both of a width Wa1 of the outer circumferential first slits 21a in the short direction and a width Wa2 of the outer circumferential second slits 22a in the short direction are preferably 0.03 mm or more and 0.6 mm or less. When the widths of the outer circumferential slits (21a, 22a) are controlled to the above-mentioned range, it is possible to appropriately restrain an abnormal deformation of the laminated body 4 while piezoelectric characteristics are maintained.

In the present embodiment, the internal electrode layers 16 can have a substantially rectangular shape from plan view. In this case, the outer circumferential first slits 21a and the outer circumferential second slits 22a are preferably formed near the corners 16c of the internal electrode layers 16.

When the lamination surface (flat surface) is substantially rectangular, the stress generated in the internal electrode layers 16 particularly affects the corners 16c of the internal electrode layers 16. Thus, the corners of the laminated body 4 are conventionally easily warped. In the multilayer piezoelectric device 2 according to the present embodiment, since the outer circumferential first slits 21a and the outer circumferential second slits 22a are formed near the corners 16c, the flatness of the laminated body 4 can further be improved.

In the present embodiment, an effective electrode area of the internal electrode layers 16 can be large by forming the outer circumferential slit pattern 20 having the above-mentioned features. That is, the rate of the non-cover part 14 can be small on the plane shown in FIG. 3A.

### Second Embodiment

Hereinafter, Second Embodiment of the present invention is explained based on FIG. 3B. Incidentally, the structure of Second Embodiment common with that of First Embodiment is not explained and given similar references.

FIG. 3B illustrates an internal electrode pattern 26b according to Second Embodiment and is an enlarged plane view of a main part of the internal electrode pattern 26b. As with the internal electrode pattern 26a according to First Embodiment, the outer circumferential slit pattern 20 including the outer circumferential first slits 21a and the outer circumferential second slits 22a is formed on the outer circumference of the internal electrode layers 16. In particular, the outer circumferential first slits 21a and the outer circumferential second slits 22a are formed near the corners 16c of the internal electrode layers 16.

As shown in FIG. 3B, Second Embodiment is characterized in that the corners 16c of the internal electrode layers 16, corners 21ac of the outer circumferential first slits 21a, and corners 22ac of the outer circumferential second slits 22a are round. Preferably, this roundness at each corner has a radius of curvature of 0.1 mm or more.

When a DC electric field is applied in polarization, the electric field tends to concentrate on the corners 16c, 21ac, and 22ac of the internal electrode layers 16. In particular, when the piezoelectric layers 10 are made of a lead-free material, a rated voltage for polarization is high, and a short circuit is easily generated at the corners 16c, 21ac, and 22ac in polarization.

In Second Embodiment, since the corners 16c of the internal electrode layers 16 and the corners 21ac and 22ac of the outer circumferential slit pattern 20 are rounded with a predetermined radius of curvature, it is possible to prevent an electric field from concentrating on the above-mentioned corners. In Second Embodiment, the multilayer piezoelectric device 2 can thereby have a large polarization rate by applying a higher voltage than before or having a higher temperature of an insulating oil in polarization. As a result, the displacement amount of the multilayer piezoelectric device 2 is further improved.

### Third Embodiment

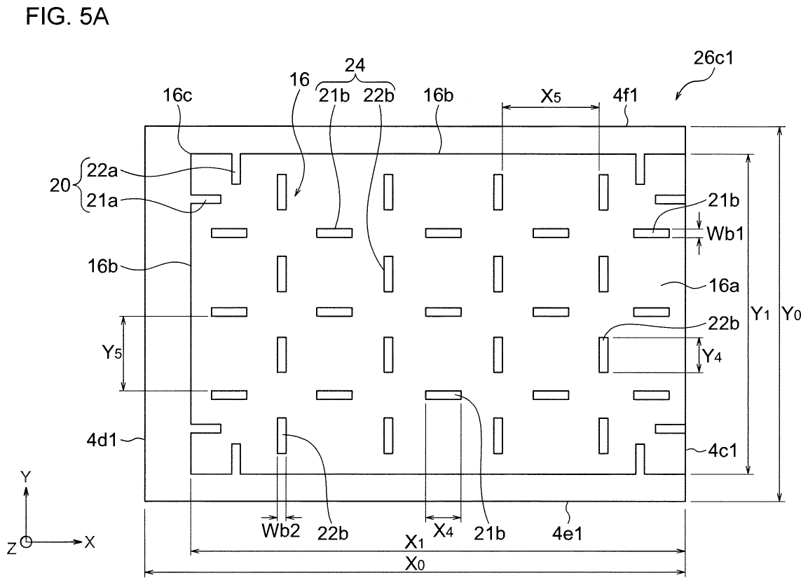

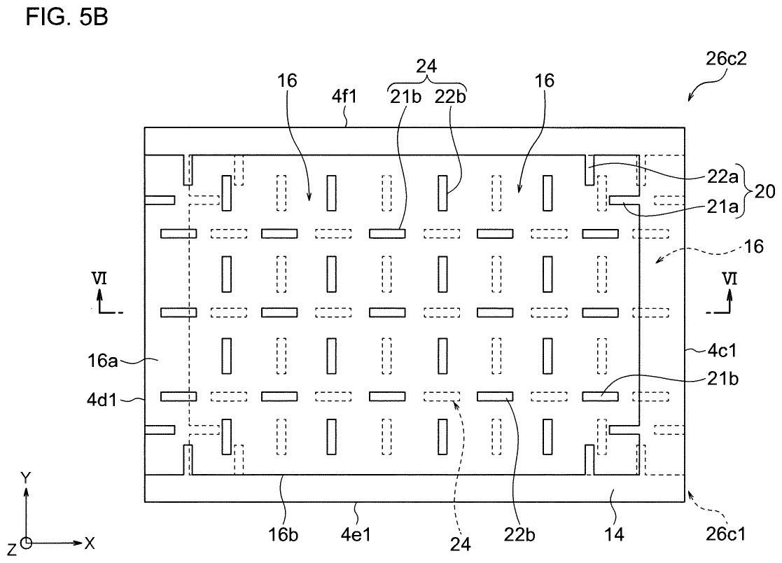

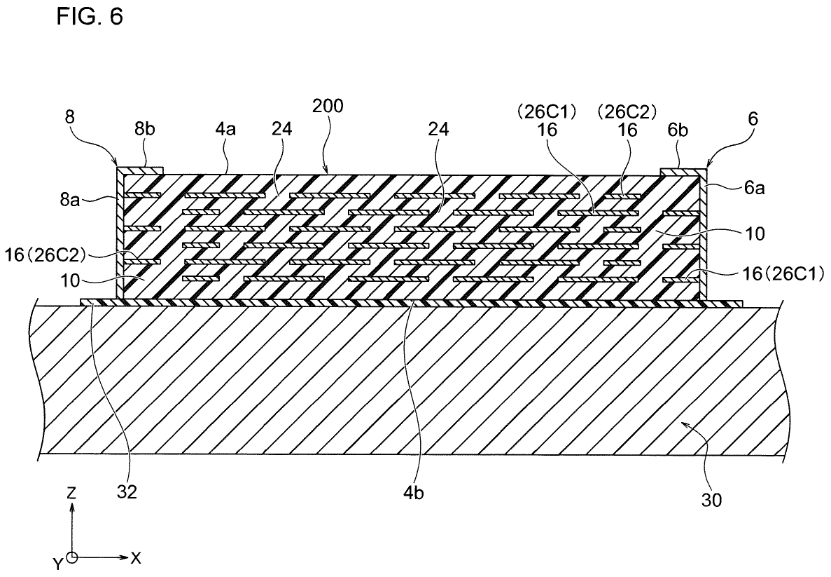

Hereinafter, Third Embodiment of the present invention is explained based on FIG. 5A, FIG. 5B, and FIG. 6. Incidentally, the structure of Third Embodiment common with that of First Embodiment is not explained and given similar references.

A multilayer piezoelectric device 200 according to Third Embodiment includes an internal electrode pattern 26c1 as shown in FIG. 5A. In the internal electrode pattern 26c1, as with the internal electrode pattern 26a according to First Embodiment shown in FIG. 3A, the outer circumferential slit pattern 20 is formed on the outer circumference of the internal electrode layers 16. The features of the outer circumferential slit pattern 20 are common between Third Embodiment and First Embodiment.

In the internal electrode pattern 26c1, in addition to the outer circumferential slit pattern 20, an inner slit pattern 24 is formed on the inner side of the internal electrode layers 16. The inner slit pattern 24 can include an inner first slit 21b parallel to the X-axis and an inner second slit 22b parallel to the Y-axis. Here, the inner side of the internal electrode layers 16 means an inner side of the outer circumferential edges 16b of the inner electrode layers 16, and the inner slit pattern 24 includes a slit (21b or 22b) that is not open at the outer circumferential edges 16b.

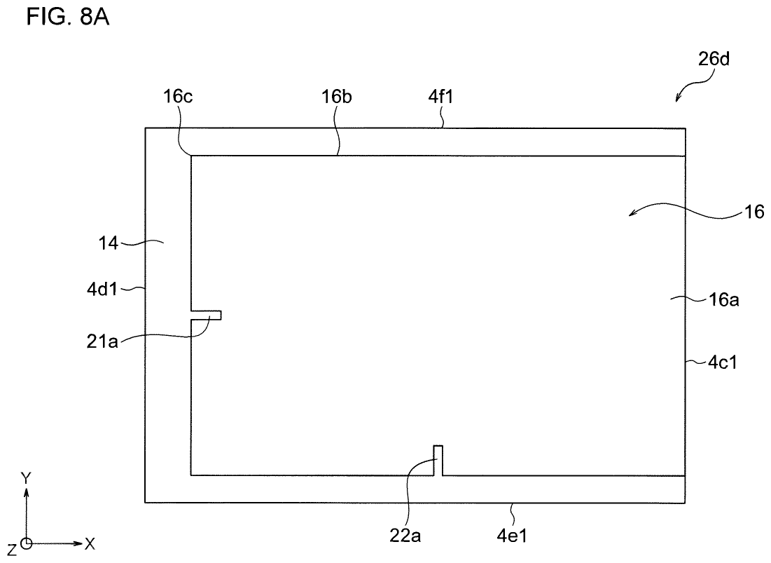

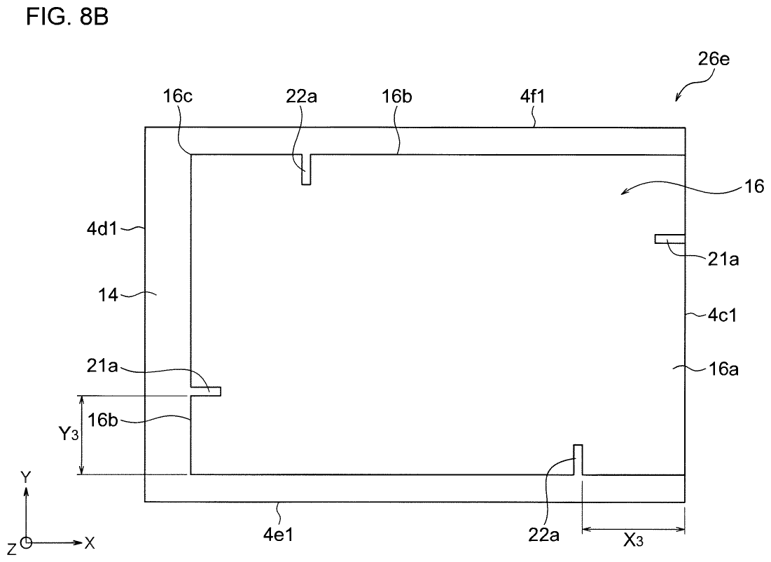

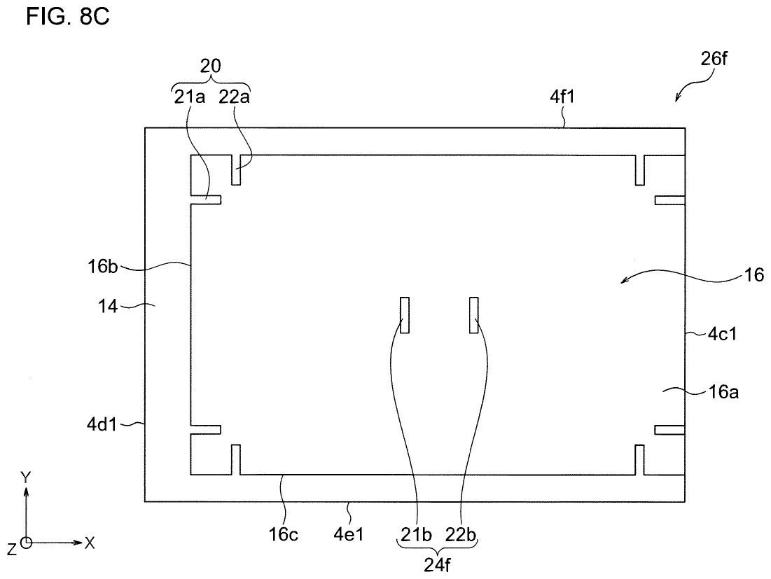

Incidentally, the inner slit pattern is formed by combining at least two of the inner first slit 21b or the inner second slit 22b. For example, as shown in FIG. 8C, the inner slit pattern 24 may be a slit pattern (inner slit pattern 24f) formed by combining only the inner second slits 22b (or only the inner first slits 21b).

As shown in FIG. 5A, however, the inner slit pattern 24 is preferably formed by combining a plurality of inner first slits 21b and a plurality of inner second slits 22b. In particular, in FIG. 5A according to Third Embodiment, the inner slit pattern 24 is a pattern formed by combining a plurality of inner first slits 21b and a plurality of inner second slits 22b in a dashed grid manner.

When the inner slit pattern 24 with a dashed grid shape is formed as mentioned above, the inner first slits 21b and the inner second slits 22b included in the inner slit pattern 24 are preferably uniformly arranged on the plane of the internal electrode layers 16. In the dashed-grid pattern, the inner first slits 21b and/or the inner second slits 22b existing at the outermost location may be open outside at the outer circumferential edges 16b of the inner electrode layers 16.

Preferably, the inner first slits 21b and the inner second slits 22b exist separately and are not connected to each other on the plane of FIG. 5A. In other words, preferably, even if the inner slit pattern 24 is formed, the internal electrode layer 16 shown in FIG. 5A is not separated by the inner first slits 21b or the inner second slits 22b and is formed integrally as a single electrode. Incidentally, as long as the internal electrode layer 16 exists integrally and continuously, the slits included in the inner slit pattern 24 (the inner first slits 21b and/or the inner second slits 22b) may be formed by partly connecting with each other.

In the inner slit pattern 24 with a dashed grid shape shown in FIG. 5A, the distance Y5 between dashed lines parallel to the X-axis can be about ⅛-½ (preferably, about ⅙-⅓) of the width Y1 of the internal electrode layers 16 in the Y-axis direction (Y5/Y1). That is, the number of dashed lines parallel to the X-axis and constituting the dashed grid can be one to eight (preferably, two to five). The distance of the dashed lines parallel to the Y-axis (X5, X5/X1) and the number of dashed lines can be similar to the mentioned-above ones. The number of dashed lines parallel to the X-axis and the number of dashed lines parallel to the Y-axis may be the same as or different from each other.

In the inner slit pattern 24, the width Wb1 in the short direction of the inner first slits 21b can be 0.01 mm to 0.8 mm (preferably, 0.03 mm to 0.6 mm). As with Wb1, the width Wb2 in the short direction of the inner second slits 22b can be 0.01 mm to 0.8 mm (preferably, 0.03 mm to 0.6 mm).

In the inner slit pattern 24, the length X4 in the longitudinal direction of the inner first slits 21b can be about 1/10- 1/7 (preferably, ⅛ or less) of the width X1 of the internal electrode layers 16 in the X-axis direction (X4/X1). Meanwhile, the length Y4 in the longitudinal direction of the inner second slits 22b can be about 1/10- 1/7 (preferably, ⅛ or less) of the width Y1 of the internal electrode layers 16 in the Y-axis direction (Y4/Y1).

FIG. 5B illustrates a state where the piezoelectric layer 10 and an internal electrode pattern 26c2 are further laminated above the internal electrode pattern 26c1 shown in FIG. 5A in the Z-axis direction. The internal electrode pattern 26c2 illustrated by the solid line in FIG. 5B has a form where the internal electrode pattern 26c1 is rotated by 180 degrees around the Z-axis. In FIG. 5B, the internal electrode pattern 26c1 located below the Z-axis direction is illustrated by the dotted line.

Compared to the internal electrode pattern 26c1, the inner slit pattern 24 of the internal electrode pattern 26c2 is disposed differently on the X-Y plane. As shown in FIG. 5B, the inner slit patterns 24 of two internal electrode layers 16 next to each other via the piezoelectric layer 10 (i.e., the internal electrode patterns 26c1 and 26c2) are not thereby overlapped with each other and locationally shifted in the lamination direction. Thus, the multilayer piezoelectric device 200 according to Third Embodiment has an X-Z cross section as shown in FIG. 6 at a substantially central location in the Y-axis direction.

In the X-Z cross section shown in FIG. 6, the inner first slits 21b or the inner second slits 22b included in the inner slit patterns 24 are confirmed as disconnected parts of the internal electrode layers 16. As shown in FIG. 6, the locations of the inner slit patterns 24 of the two internal electrode layers 16 next to each other are not overlapped and locationally shifted in the laminated direction. Incidentally, if the multilayer structure shown in FIG. 5B is employed, a Y-Z cross section (not illustrated) of the multilayer piezoelectric device 200 also has a cross-sectional form similar to the above-mentioned one.

Incidentally, the outer circumferential slit patterns 20 may be overlapped in the lamination direction or may locationally be shifted without being overlapped in the lamination direction.

In the multilayer piezoelectric device 200 according to Third Embodiment, the inner slit patterns 24 are formed along with the outer circumferential slit patterns 20 on the internal electrode layers 16. In the multilayer piezoelectric device 200, it is thereby possible to more effectively reduce cracks generated in the laminated body 4 and further improve the displacement amount. The reason why these effects can be obtained is conceivable, for example, as below.

The piezoelectric layers 10 generate a mechanical displacement by application of electric voltage via the internal electrode layers 16, but at this time, the internal electrode layers 16 themselves do not generate a mechanical displacement. Thus, the internal electrode layers 16 may disturb a mechanical displacement of the piezoelectric layers 10. In Third Embodiment, it is conceivable that the displacement disturbance by the internal electrode layers 16 can be reduced by forming the inner slit patterns 24 on the internal electrode layers 16.

In particular, as shown in FIG. 5A, the inner slit patterns 24 are preferably formed by combining a plurality of inner first slits 21b and a plurality of inner second slits 22b in a dashed grid manner. When the inner slit patterns 24 are formed in a dashed grid manner, the displacement amount of the multilayer piezoelectric device 200 is further improved.

In the inner slit patterns 24, preferably, both of the width Wb1 in the short direction of the inner first slits 21b and the width Wb2 in the short direction of the inner second slits 22b are also in a range of 0.03-0.6 mm. In the multilayer piezoelectric device 200 according to Third Embodiment, when the widths of the inner slits (21b, 22b) are controlled to the above-mentioned range, it is possible to appropriately restrain generation of cracks while piezoelectric characteristics are maintained.

In Third Embodiment, as shown in FIG. 6, a plurality of piezoelectric layers 10 and a plurality of internal electrode layers 16 can be laminated alternately in the laminated body 4. In this case, preferably, the inner slit patterns 24 of two internal electrode layers 16 next to each other via the piezoelectric layer 10 are not overlapped and locationally shifted in the lamination direction on an optional cross section of the laminated body 4 perpendicular to the X-axis or the Y-axis. In the above-mentioned lamination structure, the multilayer piezoelectric device 200 according to Third Embodiment has a further improved flatness of the laminated body 4.

Incidentally, in Third Embodiment, the outer circumferential patterns 20 are formed in the internal electrode layers 16, and effects similar to those of First Embodiment are demonstrated.

### Fourth Embodiment

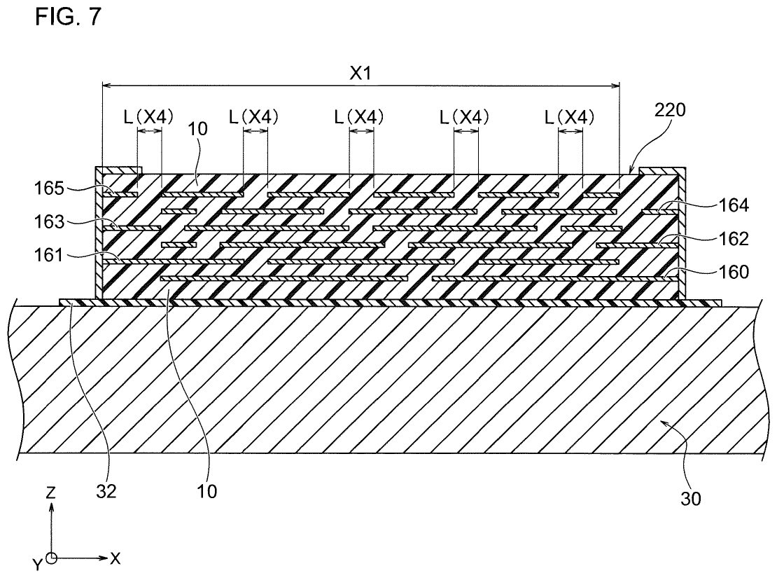

Hereinafter, Fourth Embodiment of the present invention is explained based on FIG. 7. Incidentally, the structure of Fourth Embodiment common with that of First and Third Embodiments is not explained and given similar references.

FIG. 7 is a schematic cross-sectional view of a multilayer piezoelectric device 220 according to Fourth Embodiment. In the multilayer piezoelectric device 220, the laminated body 4 is structured by alternately laminating the piezoelectric layers 10 and the internal electrode layers 16 (160-165). Incidentally, FIG. 7 illustrates a structure where six internal electrode layers are laminated, but this lamination number is just an example. The lamination number according to Fourth Embodiment is not limited to one in FIG. 7.

In Fourth Embodiment, as with Third Embodiment, the outer circumferential slit patterns 20 and inner slit patterns 240-245 are formed on internal electrode layers 160-165. In the internal electrode layers 160-165, however, the number of slits included in the inner slit patterns 240-245 (the number of the inner first slits 21b and the inner second slits 22b) is different. In the X-Z cross section shown in FIG. 7, the number of disconnection parts observed in the internal electrode layers 160-165 is accordingly different.

In other words, the multilayer piezoelectric device 220 according to Fourth Embodiment has a coverage rate of the internal electrode layers 16 per one layer gradually increasing or decreasing from the lowermost layer (internal electrode layer 160) to the uppermost layer (internal electrode layer 165) in the lamination direction.

Here, the coverage rate of the internal electrode layers 16 is a parameter showing an abundance ratio of slits (the first slit 21 and the second slit 22 (particularly, the inner first slit 21b and the inner second slit 22b)) and is specifically calculated in the following manner.

The coverage rate is calculated by observing a cross section of the laminated body 4 with SEM, optical microscope, or the like. At this time, a sample for observation is manufactured by cutting the laminated body 4 on a surface perpendicular to the X-axis or the Y-axis and subjecting the cross section to mirror polishing. “perpendicular to the X-axis or the Y-axis” means a X-Z cross section or a Y-Z cross section. The cut location is not limited. Here, as an example, the coverage rate of the uppermost layer (internal electrode layer 165) is calculated on the X-Z cross section of FIG. 7.

First of all, a length of the internal electrode layer 165 from end to end (i.e., the width X1 shown in FIG. 7) is measured on the polished cross section. Then, lengths L of disconnection parts included in the internal electrode layer 165 (L=X4 in FIG. 7) are measured to calculate their summation (EL). Incidentally, the disconnection parts here correspond to the first slits 21 or the second slits 22 included in the internal electrode layers 16. The coverage rate is represented by (X1−ΣL)/X1(%). That is, the abundance ratio of slits in the internal electrode layer 165 is large if the coverage rate is small, and the abundance ratio of slits in the internal electrode layer 165 is small if the coverage rate is large.

In Fourth Embodiment, as mentioned above, the coverage rate of the internal electrode layers 16 per one layer gradually increases or decreases from the lowermost layer to the uppermost layer in the lamination direction. “gradually increases or decreases” means that the coverage rate changes gradually, and the coverage rate may be largest on the lowermost layer side or the uppermost layer side. Moreover, the coverage rate may be largest or smallest in the internal electrode layer at the central part.

In Fourth Embodiment, since the coverage rate of the internal electrode layers 16 per one layer gradually increases or decreases, piezoelectric characteristics of the multilayer piezoelectric device 220 can be controlled to a desired value. To further improve the displacement amount of the multilayer piezoelectric device 220, for example, as shown in FIG. 7, it is preferable to increase the coverage rate of the internal electrode layer 160 on the lowermost layer side and decrease the coverage rate of the internal electrode layer 165 on the uppermost layer side.

Specifically, the internal electrode layer 160 on the lowermost layer side is bound by the vibration plate 30 and thereby preferably has a high coverage rate with emphasis on mechanical strength. On the contrary, the internal electrode layer 165 on the uppermost layer preferably has a low coverage rate so as to reduce the influence of deformation disturbance by the internal electrode layer 165. Thus, as shown in FIG. 7, the displacement amount of the multilayer piezoelectric device 220 can be larger by laminating the internal electrode layers 160-165 so that the coverage rate gradually becomes small from the lowermost layer side toward the uppermost layer side. In particular, when the multilayer piezoelectric device 220 is used for piezoelectric speakers, the sound pressure is further improved.

Meanwhile, when the coverage rate of the internal electrode layer 165 on the uppermost layer side is largest, or when the coverage rate of the internal electrode layer 162 (163) at the central part is largest or smallest, the sound quality can be changed for speaker applications.

Incidentally, when a multilayer structure where the coverage rate gradually increases or decreases as mentioned above is employed, the coverage rate can be 100% in the internal electrode layer 16 where the coverage rate is largest (160 in case of FIG. 7). That is, the inner slit pattern 24 may not be formed.

Preferably, the difference in coverage rate between the internal electrode layer 16 having a maximum coverage rate (160 in case of FIG. 7) and the internal electrode layer 16 having a minimum coverage rate (165 in case of FIG. 7) is within a range of 3.0% or more and 15% or less. When the coverage rate is increased or decreased within this range, piezoelectric characteristics can be changed greatly. That is, the displacement amount is further improved (the sound pressure becomes larger) in the multilayer structure of FIG. 7.

Hereinbefore, the present invention is explained based on embodiments shown in the figures, but the present invention is not limited to the above-mentioned embodiments and may variously be changed within the scope of the present invention. In the above-mentioned embodiments, for example, the multilayer piezoelectric devices 2, 200, and 220 have a substantially rectangular shape from plain view, but may have any other shape from plain view, such as circle, oval, polygon, and parallelogram. This is also the case with the vibration plate 30, and the vibration plate 30 may have a shape from plain view, such as circle, oval, and polygon. The vibration plate 30 may not necessarily be used depending upon the usage of the multilayer piezoelectric device.

In the above-mentioned embodiments, the piezoelectric layers 10 have the non-cover part 14 not covered with the internal electrode layers 16 on the plane shown in FIG. 3A. A dummy electrode layer electrically insulated with the internal electrode layer 16 may be formed on the non-cover part 14. In the above-mentioned embodiments, the leading portions 16a are formed by partly exposing the internal electrode layers 16 to the side surfaces of the laminated body 4. The leading portions may be substituted by forming via hole electrodes in the laminated body 4. In this case, the pair of external electrodes 6 and 8 is formed on the front surface 4a or the back surface 4b of the laminated body 4 by corresponding to the locations of the via hole electrodes.

In the above-mentioned embodiments, the first slits 21 are parallel to the X-axis, and the second slits 22 are parallel to the Y-axis, but the first slits 21 and the second slits 22 may be formed in any other direction excluding the ones of the embodiments. The first slits 21 and the second slits 22 may be formed in any direction as long as they intersect each other. Specifically, the first direction where the first slits 21 are formed is changeable by ±45 degrees to the X-axis. Likewise, the second direction where the second slits 22 are formed is changeable by ±45 degrees to the Y-axis. For example, the inner slit pattern 24 with a dashed grid shape may be formed by being rotated from the state of FIG. 5A by 45 degrees or less around the Z-axis.

In FIG. 5A and FIG. 5B, both of the outer circumferential slit pattern 20 and the inner slit pattern 24 are formed in the internal electrode layers 16, but only the inner slit pattern 24 may be formed.

The multilayer piezoelectric device according to the present invention can be utilized as a conversion element for electrical energy and mechanical energy. For example, the multilayer piezoelectric device according to the present invention is applicable to drive actuators, haptics devices, piezoelectric buzzers, piezoelectric sounders, ultrasonic motors, speakers, etc. and is particularly advantageously utilized for haptics and piezoelectric speakers.

### EXAMPLES

Hereinafter, the present invention is explained based on further detailed examples, but is not limited to the examples.

### Experiment 1

### Example 1

In Example 1, internal electrode layers 16 were formed with an internal electrode pattern 26d shown in FIG. 8A to manufacture samples of a multilayer piezoelectric device.

As shown in FIG. 8A, the internal electrode pattern 26d included one outer circumferential first slit 21a and one outer circumferential second slit 22a and included no inner slit pattern 24. In the internal electrode pattern 26d, the slits were not formed near corners 16c of the internal electrode layer 16, but the outer circumferential first slit 21a was formed at a substantially central location in the Y-axis direction, and the outer circumferential second slit 22a was formed at a substantially central location in the X-axis direction. The details of a method of manufacturing the samples of the multilayer piezoelectric device according to Example 1 are as follows.

First of all, predetermined amounts of chemically pure main component raw materials and sub component raw materials were weighed so that piezoelectric layers would be composed of PZT based ceramics and were mixed in wet manner by a ball mill. After the mixing, the mixture was calcined at 800° C. to 900° C. and pulverized in the ball mill. The calcined powder obtained in this manner was added with a binder to be turned into a slurry. Moreover, the slurry was turned into sheets by screen printing method and thereafter dried to obtain ceramic green sheets.

Next, a conductive paste containing Ag—Pd alloy as a main component was applied onto the ceramic green sheets. At this time, the conductive past was applied by patterning so that the internal electrode pattern 26d shown in FIG. 8A would be formed after firing.

The green sheets obtained in this manner were laminated by nine layers in a predetermined order to obtain a green chip. In addition, this green chip was bonded with pressure, dried, debindered, and fired. Incidentally, the firing was carried out at 900° C. (furnace temperature) under atmospheric conditions. After this step, a laminated body sample according to Example 1 was obtained.

Incidentally, the laminated body sample according to Example 1 had a substantially rectangular parallelepiped shape and the size of width (X0) 30 mm×depth (Y0) 30 mm×thickness 0.1 mm. The thickness of the piezoelectric layers 10 was 10 μm on average. The thickness of the internal electrode layers 16 was 1 μm on average. In Example 1, the width in the short direction of an outer circumferential slit 21a (22a) was about 0.1 mm.

The laminated body sample manufactured in this manner was attached with a pair of external electrodes 6 and 8 and thereafter polarized to manufacture samples of a multilayer piezoelectric device. In Example 1, 1000 samples of a multilayer piezoelectric device were manufactured and evaluated in the following manner.

### Measurement of Flatness

The flatness of the laminated body samples obtained in Example 1 was measured to evaluate the existence of abnormal deformation. The flatness of the laminated body samples was measured using a CNC image measuring machine (NIXIV VMZ-R6555, manufactured by Nikon Instech Co., Ltd.). Specifically, the flatness was measured by making a least square plane based on a height data obtained by irradiating the laminated body with laser light and calculating a maximum height and a minimum height with the least squares plane as a reference plane. The flatness is represented by (the maximum height−the minimum height). The smaller the flatness is, the less likely the laminated body is abnormally deformed.

Incidentally, the measurement was carried out 900 times per example. This average is shown in Table 1 as a measurement result. As for the flatness, 200 μm is a Pass/Fail criterion. A flatness of 150 μm or less was considered to be favorable, and a flatness of 100 μm or less was considered to be more favorable.

### Evaluation of Cracks

The evaluation of cracks was carried out by observing cross sections of the laminated body samples by FE-SEM. Specifically, a crack incidence was calculated in the following manner. First of all, 100 samples were selected at random from the 1000 laminated body samples and fixed to a resin to subject an optional cross section to mirror polishing. Then, samples for SEM observation were obtained. In the observation of the cross section of each sample, a crack incidence was calculated by counting the number of samples having cracking in the piezoelectric layers 10, peeling between the piezoelectric layers 10 and the internal electrode layer 16, or the like. As for the crack incidence, 10% or less was considered to be a favorable range, and 5% or less was considered to be a more favorable range.

### Measurement of Sound Pressure

As for the multilayer piezoelectric device samples obtained in Example 1, a sound pressure was measured to evaluate deformation characteristics. As a pre-step before measuring the sound pressure, the multilayer piezoelectric device samples were initially adhered to the surface of a vibration plate made of Ni—Fe alloy using an adhesive of Kyoritsu Chemical Industry World Rock 830. The size of the vibration plate was 80 mm×60 mm. The application amount of the adhesive was controlled to be constant in all of the samples.

In the measurement of the sound pressure, a piezoelectric element was attached onto a central area of a glass plate of 220 mm length×220 mm width×0.7 mm thickness using a double-sided tape, and the glass plate was inserted into a fixing jig. At this time, the distance from an evaluation surface to a sound pressure gauge was adjusted to 100 mm. Then, a function generator was connected to the piezoelectric element, and the piezoelectric element was applied with voltage at 100 Hz-20 kHz (frequency of sine wave) and 12 Vp-p (output voltage of the function generator). The vibration of the piezoelectric element generated at this time was measured as the sound pressure using a sound pressure microphone. As for the sound pressure, 73 dB was considered to be a Pass/Fail criterion. A sound pressure of 80 dB or more was considered to be favorable, and a sound pressure of 90 dB or more was considered to be more favorable.

### Example 2

In Example 2, internal electrode layers 16 were formed with an internal electrode pattern 26e shown in FIG. 8B to manufacture samples of a multilayer piezoelectric device. As shown in FIG. 8B, the internal electrode pattern 26e included two outer circumferential first slits 21a and two outer circumferential second slits 22a and included no inner slit pattern.

In the internal electrode pattern 26e, the slits 21a and 22a were not formed near the corners 16c of the internal electrode layer 16, but formed on the center side. Specifically, the outer circumferential first slits 21a were formed so that the distance Y3 from the corners 16c to the formation location was about ⅓ of Y1. Likewise, the outer circumferential second slits 22a were formed so that the distance X3 from the corners 16c to the formation location was about ⅓ of X1.

The structure of Example 2 except for the above-mentioned one was common with that of Example 1. Evaluations similar to those of Example 1 were carried out in Example 2. The results are shown in Table 1.

### Example 3

In Example 3, internal electrode layers 16 were formed with an internal electrode pattern 26a shown in FIG. 3A to manufacture samples of a multilayer piezoelectric device. As explained in First Embodiment, four outer circumferential first slits 21a and four outer circumferential second slits 22a were formed in the internal electrode pattern 26a. In particular, the slits 21a and 22a were formed near the corners 16c of the internal electrode layer 16. Incidentally, no inner slit pattern 24 was formed in Example 3. The structure of Example 3 except for the above-mentioned one was common with that of Example 1. Evaluations similar to those of Example 1 were carried out in Example 3. The results are shown in Table 1.

### Example 4

In Example 4, internal electrode layers 16 were formed with an internal electrode pattern 26f shown in FIG. 8C were formed to manufacture samples of a multilayer piezoelectric device. In the internal electrode pattern 26f, an outer circumferential slit pattern 20 was formed in a similar form to Example 3. In the internal electrode pattern 26f, an inner slit pattern 24f having two internal second slits 22b was additionally formed in a central area of the internal electrode layer 16. Incidentally, the width in the short direction of the inner slits was about 0.1 mm in Example 4. The structure of Example 4 except for the above-mentioned one was common with that of Example 1. Evaluations similar to those of Example 1 were carried out in Example 4. The results are shown in Table 1.

### Example 5

In Example 5, internal electrode layers 16 were formed with an internal electrode pattern 26c1 shown in FIG. 5A to manufacture samples of a multilayer piezoelectric device. As explained in Third Embodiment, the internal electrode pattern 26c1 was characterized in that an inner slit pattern 24 with a dashed grid shape was formed with an outer circumferential slit pattern 20. In the laminated body samples of Example 5, however, the inner slit patterns 24 next to each other via the piezoelectric layer 10 were partly overlapped with each other in the lamination direction. The structure of Example 5 except for the above-mentioned one was common with that of Example 1. Evaluations similar to those of Example 1 were carried out in Example 5. The results are shown in Table 1.

### Example 6

In Example 6, as shown in FIG. 5B, internal electrode layers 16 were formed with internal electrode patterns 26c1 and 26c2 to manufacture samples of a multilayer piezoelectric device. In particular, the inner slit patters 24 of the laminated body samples of Example 6 next to each other via the piezoelectric layer 10 were locationally shifted without overlapping with each other in the lamination direction (i.e., the multilayer structure of FIG. 6). The structure of Example 6 except for the above-mentioned one was common with that of Example 5. Evaluations similar to those of Example 5 were carried out in Example 6. The results are shown in Table 1.

### Comparative Example 1

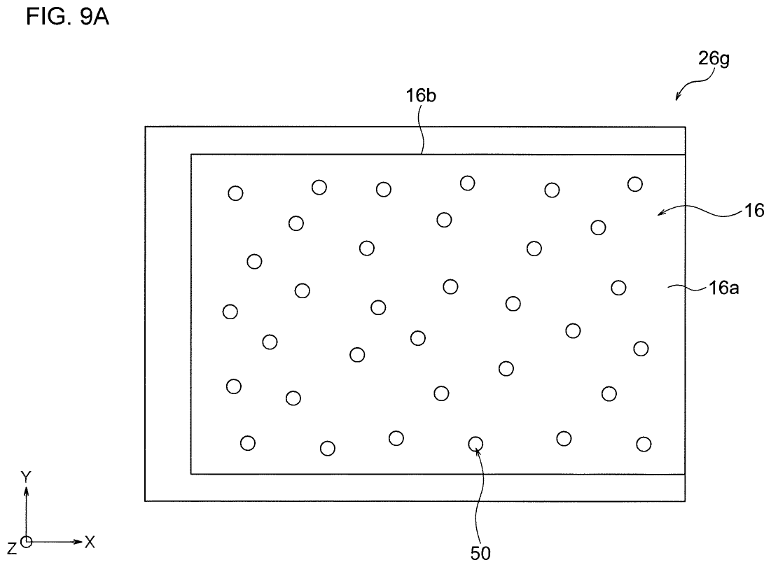

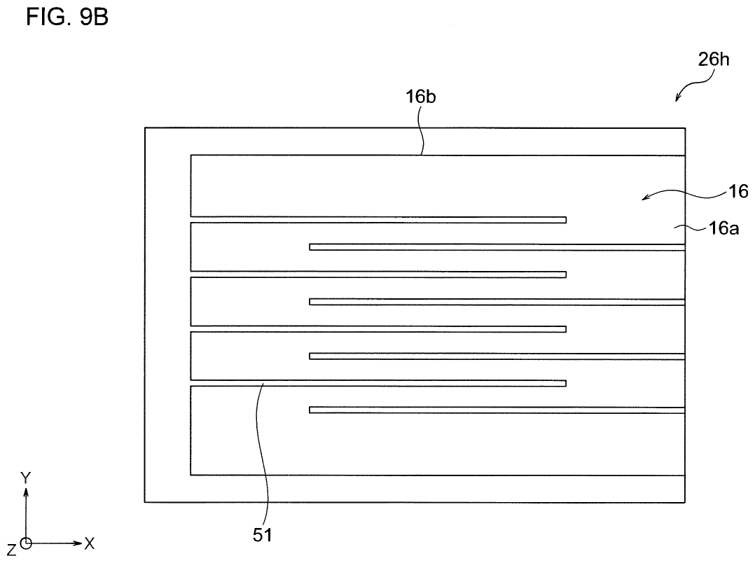

In Comparative Example 1, internal electrode layers 16 were formed with an internal electrode pattern 26g shown in FIG. 9A to manufacture samples of a multilayer piezoelectric device. In the internal electrode pattern 26g shown in FIG. 9A, no slit corresponding to the outer circumferential slit pattern 20 was formed. In the internal electrode pattern 26g, a plurality of circular holes 50 (diameter: about 0.1 mm) was formed on the inner side of the internal electrode layers 16. The structure of Comparative Example 1 except for the above-mentioned one was common with that of Example 1. Evaluations similar to those of Example 1 were carried out in Comparative Example 1. The results are shown in Table 1.

### Comparative Example 2

In Comparative Example 2, internal electrode layers 16 were formed with an internal electrode pattern 26h shown in FIG. 9B to manufacture samples of a multilayer piezoelectric device. As shown in FIG. 9B, the internal electrode pattern 26h had slits 51 formed only in a parallel direction to the X-axis. In the slits 51 of the internal electrode pattern 26h, the length in the longitudinal direction was ½ or more of the width X1 of the internal electrode layer 16 and was formed continuously from the outer circumference toward the inner side of the internal electrode layer 16. The structure of Comparative Example 2 except for the above-mentioned one was common with that of Example 1. Evaluations similar to those of Example 1 were carried out in Comparative Example 2. The results are shown in Table 1.

TABLE 1

| | Form of | | | | Inner Slit Pattern | | | | |
|---|---|---|---|---|---|---|---|---|---|
| | Internal | Outer Circumferential Slit Pattern | | | Existence | Locational Shift | Evaluation Characteristics | | |
| Sample | Electrode | Existence of | Number of Slits | | of | in Lamination | Flatness | Crack | Sound |
| No. | Pattern | Formation | First Slit | Second Slit | Formation | Direction | μm | Incidence % | Pressure dB |
| Comp. Ex. 1 | FIG. 9A | no | — | — | yes | no | 572 | 12 | 71 |
| Comp. Ex. 2 | FIG. 9B | yes | 0 | 8 | yes | no | 485 | 13 | 69 |
| Ex. 1 | FIG. 8A | yes | 1 | 1 | no | — | 144 | 7 | 76 |
| Ex. 2 | FIG. 8B | yes | 2 | 2 | no | — | 102 | 7 | 77 |
| Ex. 3 | FIG. 3A | yes | 4 | 4 | no | — | 64 | 7 | 77 |
| Ex. 4 | FIG. 8C | yes | 4 | 4 | yes | no | 60 | 2 | 81 |
| Ex. 5 | FIG. 5A | yes | 4 | 4 | yes | no | 91 | 5 | 84 |
| Ex. 6 | FIG. 5B | yes | 4 | 4 | yes | yes | 54 | 1 | 88 |

In Comparative Example 1 and Comparative Example 2, the laminated body samples had an abnormal deformation (e.g., warp, swell), and the flatness was as bad as 500 μm as shown in Table 1. In Comparative Example 1 and Comparative Example 2, the crack incidence was 10% or more, which failed to satisfy the criterion. In accordance with the abnormal deformation and the generation of cracks, the sound pressures of Comparative Example 1 and Comparative Example 2 were a low standard of 73 dB or less.

In Comparative Example 1, since no slits were formed on the outer circumference of the internal electrode layers 16, which was easily affected by internal stress, it is conceivable that the stress could not sufficiently be reduced. Thus, the flatness is not thereby expected to improve only by forming the holes 50 on the inner side of the internal electrode layers 16 like Comparative Example 1.

Meanwhile, Comparative Example 2 had elongated slits 51 formed to contact with outer circumferential edges 16b of the internal electrode layer 16. In the internal electrode pattern 26h of Comparative Example 2, however, the slits 51 were formed only in one direction, and it is thereby conceivable that the stress could not sufficiently be reduced. Thus, the flatness is not expected to improve only by forming the slits 51 only in one direction like Comparative Example 2.

On the other hand, all characteristics (flatness, crack incidence, and sound pressure) of Examples 1-6 according to the present invention were more favorable than those of Comparative Examples 1 and 2 and satisfied their criteria. This result shows that when the slits were formed along both of the X-axis direction and the Y-axis direction, the stress was easily reduced, and that it was possible to improve the flatness and restrain the generation of cracks.

Comparing the results of Examples 1-3 in Table 1, it is found that the flatness became small by increasing the number of slits included in the outer circumferential slit pattern 20. In particular, the flatness of Example 3 was the most favorable. This result shows that the flatness was further improved when the total number of outer circumferential slits (21a, 22a) was at least four or more. It was also confirmed that, like Example 3, the flatness of the laminated body 4 was further improved by forming the outer circumferential slits 21a and 22a in the surroundings of the corners 16c.

Comparing Examples 1-3 with Examples 4-6, it is found that Examples 4-6, which had an inner slit pattern, exhibited a lower crack incidence and a larger sound pressure than those of Examples 1-3. This result shows that when both of the outer circumferential slit pattern and the inner slit pattern were formed in the internal electrode layer 16, it was possible to more effectively reduce cracks generated in the laminated body 4 and further increase the displacement amount of the multilayer piezoelectric device.

Comparing Examples 4-6, the sound pressure of Examples 5 and 6, which had a dashed-grid inner slit pattern, was larger than that of Example 4. In particular, all characteristics (flatness, crack incidence, and sound pressure) of Example 6 were improved. This result shows that when the inner slit pattern had a dashed grid shape, the displacement amount of the multilayer piezoelectric device was larger. It is also found that, like Example 6, the shifted location of the inner slit patterns in the lamination direction further improved the flatness of the laminated body 4 and contributed to improvement in crack restraint effect and deformation amount.

### Experiment 2

In Experiment 2, samples of a multilayer piezoelectric device were manufactured by changing the width of slit (21, 22) formed on internal electrode layers 16, and characteristics of the samples were evaluated.

### Examples 11-15

In Examples 11-15, as with Example 3 of Experiment 1, an outer circumferential slit pattern 20 shown in FIG. 3A was formed in the internal electrode layers 16. In Examples 11-15, samples of a multilayer piezoelectric device of each Example were manufactured with a changed width (Wa1, Wa2) in the short direction of an outer circumferential slit (21a, 22a). The experimental conditions of Examples 11-15 except for the above-mentioned one were common with those of Experiment 1. Evaluations similar to those of Experiment 1 were carried out in Examples 11-15. The results are shown in Table 2.

### Examples 21-25

In Examples 21-25, as with Example 6 of Experiment 1, an outer circumferential slit pattern (20, 24) shown in FIG. 5B was formed in internal electrode layers 16. In Examples 21-25, samples of a multilayer piezoelectric device of each Example were manufactured with a changed width (Wb1, Wb2) in the short direction of an inner slit (21b, 22b). In each Example, the inner slit patterns of the internal electrode layers next to each other were locationally shifted in the lamination direction. The experimental conditions of Examples 21-25 except for the above-mentioned one were common with those of Experiment 1. Evaluations similar to those of Experiment 1 were carried out in Examples 21-25. The results are shown in Table 3.

TABLE 2

| | | Outer | | | |
|---|---|---|---|---|---|
| | Form of | Circumferential | Evaluation Characteristics | | |
| | Internal | Slit Pattern | Flat- | Crack | Sound |
| Sample | Electrode | Slit Width | ness | Incidence | Pressure |
| No. | Pattern | (Wa1, Wa2) mm | μm | % | dB |
| Ex. 11 | FIG. 3A | 0.01 | 157 | 7 | 77 |
| Ex. 12 | FIG. 3A | 0.03 | 136 | 7 | 78 |
| Ex. 13 | FIG. 3A | 0.1 | 64 | 7 | 77 |
| Ex. 14 | FIG. 3A | 0.6 | 62 | 8 | 76 |
| Ex. 15 | FIG. 3A | 0.8 | 64 | 7 | 73 |

TABLE 3

| | Form of | Inner Slit Pattern | Evaluation Characteristics | | |
|---|---|---|---|---|---|
| | Internal | Slit Width | | Crack | Sound |
| Sample | Electrode | (Wb1, Wb2) | Flatness | Incidence | Pressure |
| No. | Pattern | mm | μm | % | dB |
| Ex. 21 | FIG. 5B | 0.01 | 60 | 6 | 87 |
| Ex. 22 | FIG. 5B | 0.03 | 58 | 3 | 88 |
| Ex. 23 | FIG. 5B | 0.1 | 54 | 1 | 88 |
| Ex. 24 | FIG. 5B | 0.6 | 71 | 5 | 84 |
| Ex. 25 | FIG. 5B | 0.8 | 82 | 1 | 82 |

As shown in Table 2, it is found from comparison among Examples 11-15 that the flatness of Examples 12-15 was more favorable than that of Example 11 (small slit width). It is also found that the sound pressure of Examples 11-14 was larger than that of Example 15 (large slit width). These results show that it was preferable to control the width of the outer circumferential slit (21a, 22a) to a range of 0.03 mm to 0.6 mm.

As shown in Table 3 it is found from comparison among examples 21-25 that the crack incidence of Examples 22-25 was lower than that of Example 21 (small slit width). It is also found that the sound pressure of Examples 21-24 was larger than that of Example 25 (large slit width). These results show that it was preferable to control the width of the inner slit (21b, 22b) to a range of 0.03 mm to 0.6 mm.

### Experiment 3

In Experiment 3, samples of a multilayer piezoelectric device were manufactured by changing the coverage rate of internal electrode layers 16, and characteristics of the samples were evaluated.

### Examples 31-35

In Examples 31-35, samples of a multilayer piezoelectric device were manufactured by laminating nine internal electrode layers having different coverage rates (i.e., the number of slits was different). In particular, the internal electrode layers of Examples 31-35 were laminated so that the coverage rate gradually decreased from the lowermost layer to the uppermost layer. Table 4 shows measurement results of the coverage rate at the lowermost layer and the coverage rate at the uppermost layer in each of Examples 31-35. Incidentally, the experiment conditions except for the above-mentioned one were common with those of Example 6 of Experiment 1. Table 4 shows measurement results of the sound pressure of Examples 31-35.

TABLE 4

| | | Coverage Rate of Internal | | | Evaluation |
|---|---|---|---|---|---|
| | Form of | Electrode Layer | | | Characteristic |
| | Internal | Lowermost | Uppermost | Difference in | Sound |
| Sample | Electrode | Layer % | Layer % | Coverage | Pressure |
| No. | Pattern | (average) | (average) | Rate % | dB |
| Ex. 31 | FIG. 5B | 95 | 95 | 0 | 88 |
| Ex. 32 | FIG. 5B | 95 | 92 | 3 | 92 |
| Ex. 33 | FIG. 5B | 95 | 87 | 8 | 94 |
| Ex. 34 | FIG. 5B | 95 | 80 | 15 | 90 |
| Ex. 35 | FIG. 5B | 95 | 73 | 22 | 82 |

As shown in Table 4, it is found from comparison among Examples 31-35 that the sound pressure of Examples 32-34 was particularly improved. This result shows that piezoelectric characteristics were affected by gradually changing the coverage rate of the internal electrode layers in the lamination direction. It is particularly found that the sound pressure was able to be further improved by gradually decreasing the coverage rate with a predetermined rate (3-15%) from the lowermost layer to the uppermost layer.

### Experiment 4

### Examples 41 and 42

As with Example 6 of Experiment 1, samples of a multilayer piezoelectric device of Example 41 were manufactured. Meanwhile, samples of a multilayer piezoelectric device of Example 42 were manufactured with round corners (16c, 21ac, 22ac) having a radius of curvature of 0.1 mm or more in outer circumferential edges 16b of internal electrode layers 16.

In Experiment 4, the samples were manufactured with different conditions in polarization between Example 41 and Example 42. Specifically, the polarization treatment of Example 41 was carried out by applying a DC electric field of 3 kV/mm in an insulating oil of 90° C. Meanwhile, the polarization treatment of Example 42 was carried out with conditions severer than those of Example 41 to confirm the effect of roundness. Specifically, the polarization treatment of Example 42 was carried out by applying a DC electric field of 3 kV/mm in an insulating oil of 120° C.

The experimental conditions except for the above-mentioned one were common between Example 41 and Example 42. The measurement results of sound pressure according to Examples 41 and 42 are shown in Table 5.

TABLE 5

| | | | Evaluation Characteristic |
|---|---|---|---|
| Sample | Form of Internal | Roundness | Sound Pressure |
| No. | Electrode Pattern | of Corners | dB |
| Ex. 41 | FIG. 5B | no | 88 |
| Ex. 42 | FIG. 5B and FIG. 3B | yes | 93 |

As shown in Table 5, no short-circuit failure was generated in Example 42 even though the polarization treatment was carried out with conditions severer than those of Example 41. As a result, the sound pressure of Example 42 was able to be improved better than that of Example 41. This shows that an electric field concentration on the corners was able to be restrained with the round corners (16c, 21ac, 22ac). It is also found that restraining an electric field concentration on the corners was able to increase the polarization rate of the piezoelectric layers 10 and further increase the displacement amount of the multilayer piezoelectric device.

### DESCRIPTION OF THE REFERENCE NUMERICAL

1 . . . piezoelectric device
2, 200, 220 . . . multilayer piezoelectric device
4 . . . laminated body
4a . . . front surface of laminated body
4b . . . back surface of laminated body
4c-4f . . . side surface of laminated body
10 . . . piezoelectric layer
12 . . . piezoelectric active section
14 . . . non-cover part
26a-26f . . . internal electrode pattern
16, 160-165 . . . internal electrode layer
16a . . . leading portion
16b . . . outer circumferential edge
16c . . . corner
21 . . . first slit
21a . . . outer circumferential first slit
21b . . . inner first slit
22 . . . second slit
22a . . . outer circumferential second slit
22b . . . inner second slit
20 . . . outer circumferential slit pattern
24 . . . inner slit pattern
6 . . . first external electrode
6a . . . first side-surface section
6b . . . first front-surface section
8 . . . second external electrode
8a . . . second side-surface section
8b . . . second front-surface section
30 . . . vibration plate
32 . . . adhesive layer

What is claimed is:

1. A multilayer piezoelectric device comprising:
a laminated body including:
a piezoelectric layer formed along a plane including a first axis and a second axis intersecting each other; and
an internal electrode layer laminated on the piezoelectric layer; and
an external electrode electrically connected to the internal electrode layer,
wherein the internal electrode layer includes a first slit parallel to the first axis and a second slit parallel to the second axis.

2. The multilayer piezoelectric device according to claim 1, wherein
the first slit includes an outer circumferential first slit formed on an outer circumference of the internal electrode layer, and
the second slit includes an outer circumferential second slit formed on an outer circumference of the internal electrode layer.

3. The multilayer piezoelectric device according to claim 2, wherein both a width in a short direction of the outer circumferential first slit and a width in a short direction of the outer circumferential second slit are 0.03 mm or more and 0.6 mm or less.

4. The multilayer piezoelectric device according to claim 2, wherein the outer circumferential first slit and the outer circumferential second slit have a total number of at least four slits formed at a plurality of locations on the outer circumference of the internal electrode layer.

5. The multilayer piezoelectric device according to claim 2, wherein
the internal electrode layer has a quadrangular shape from plan view on the plane, and
the outer circumferential first slit and the outer circumferential second slit are formed near a corner of the internal electrode layer.

6. The multilayer piezoelectric device according to claim 2, wherein a corner of the internal electrode layer and corners of the outer circumferential first slit and the outer circumferential second slit are rounded with a radius of curvature of 0.1 mm or more.

7. The multilayer piezoelectric device according to claim 1, wherein
the first slit includes at least one of inner first slits,
the second slit includes at least one of inner second slits,
an inner slit pattern is formed on an inner side of the internal electrode layer, and
the inner slit pattern has a combined pattern of at least two of the inner first slits or at least two of the inner second slits.

8. The multilayer piezoelectric device according to claim 7, wherein the inner slit pattern has a pattern in which a plurality of inner first slits and a plurality of inner second slits are combined in a dashed grid manner.

9. The multilayer piezoelectric device according to claim 7, wherein both a width in a short direction of the inner first slit and a width in a short direction of the inner second slit are 0.03-0.6 mm in the inner slit pattern.

10. The multilayer piezoelectric device according to claim 7, wherein
a plurality of piezoelectric layers and a plurality of internal electrode layers are alternately laminated in the laminated body, and
the inner slit patterns of two internal electrode layers next to each other via the piezoelectric layer are locationally shifted without overlapping with each other in a lamination direction on an optional cross section of the laminated body perpendicular to the first axis or the second axis.

11. The multilayer piezoelectric device according to claim 1, wherein
a plurality of piezoelectric layers and a plurality of internal electrode layers are alternately laminated in the laminated body, and
coverage rates of the internal electrode layers per one layer gradually increase or decrease from a lowermost layer to an uppermost layer in a lamination direction on an optional cross section of the laminated body perpendicular to the first axis or the second axis.

12. The multilayer piezoelectric device according to claim 11, wherein a difference of the coverage rates between the internal electrode layer having a maximum coverage rate and the internal electrode layer having a minimum coverage rate is 3.0% or more and 15% or less.
